(19) United States
(12) Patent Application Publication
(10) Pub. No.: US 2015/0087108 A1
(43) Pub. Date: Mar. 26, 2015

(54) Process, Film, and Apparatus for Top Cell for a PV Device

(71) Applicant: TEL Solar AG, Trubbach (CH)

(72) Inventors: Elena Lorena Salabas, Gams (CH); Eduard Kuegler, Klaus (AT); Chloe Prigent, Acigne (FR); Aurel Salabas, Gams (CH)

(21) Appl. No.: 14/498,304

(22) Filed: Sep. 26, 2014

Related U.S. Application Data
(60) Provisional application No. 61/882,648, filed on Sep. 26, 2013.
(60) Provisional application No. 61/911,079, filed on Dec. 3, 2013.

(51) Int. Cl. H01L 31/20; C23C 16/52; C23C 16/509

(52) U.S. Cl. CPC H01L 31/202; C23C 16/5096; C23C 16/52
USPC 438/96; 118/723 E

(57) ABSTRACT

This disclosure describes systems and methods for making at least a portion of a photovoltaic device. This may include a method of manufacturing, an optimization procedure and an apparatus for the PECVD (plasma enhanced chemical vapor deposition) of thin films over large area substrates. In particular, the system may be used to deposit thin film silicon material for photovoltaic (PV) applications. The photovoltaic device may be achieved by a combination of plasma chamber design (e.g., inter-electrode separation) and plasma process parameters (e.g., pressure, applied RF voltage, etc.) to optimize the doped and/or intrinsic layers of the solar cell (e.g., p-i-n junction).

### CROSS REFERENCE TO RELATED APPLICATIONS

This application claims priority to provisional application No. 61/882,648 filed Sep. 26, 2013 and to provisional application No. 61/911,079 filed Dec. 3, 2013. The provisional applications are incorporated by reference in their entirety into this application.

### TECHNICAL FIELD

This invention relates generally to a method of manufacturing, an optimization procedure and an apparatus for the PECVD (plasma enhanced chemical vapor deposition) of thin films over large area substrates. In particular, the system is used to deposit thin film silicon material for photovoltaic (PV) applications.

### BACKGROUND

Technological plasmas usually referred as “low-temperature plasma” are widely used in plasma assisted technologies in numerous applications such as surfaces functionalization (e.g. surface hardening through ion implantation), material treatments (e.g. hydrophilic or hydrophobic textile), thin film deposition and etching (e.g. thin film photovoltaic panels), sterilization of medical equipment's or satellite propulsion.

Plasma deposition or etching of thin film is a versatile and powerful technology adopted in many sensitive industrial applications like microelectronics or photovoltaics. In particular, the capacitively coupled plasmas (CCP) adopted in many PECVD systems combine technological simplicity and reduced costs with accurate and reliable performance.

The progress of the photoelectric conversion efficiency shows a rather small improvement over the decades, and is still far from the theoretical maximum efficiency. Independent of the strategies adopted by researchers and engineers, in this moment, the large area mass production thin film technology is not yet able to offer a full control of the inherent electrical and optical losses occurring within the bulk and at material interfaces through an adequate effective process sustained in a low-cost apparatus.

Hence, it may be desirable to achieve any conversion efficiency improvements for a PV device or cell using amorphous silicon layers a new and non-obvious way.

### BRIEF DESCRIPTION OF THE FIGURES

The features within the drawings are numbered and are cross-referenced with the written description. Generally, the first numeral reflects the drawing number where the feature was first introduced, and the remaining numerals are intended to distinguish the feature from the other notated features within that drawing. However, if a feature is used across several drawings, the number used to identify the feature in the drawing where the feature first appeared will be used. Reference will now be made to the accompanying drawings, which are not necessarily drawn to scale and wherein:

FIG. 1 is a simplified block diagram of a representative plasma processing system as described in one or more embodiments of the disclosure.

FIG. 2 is a cross sectional view of a photovoltaic device described in one or more embodiments of the disclosure.

FIG. 3 is a flow diagram for a method used to manufacture a photovoltaic device as described in one or more embodiments of the disclosure.

FIG. 4 is a flow diagram for a method used to manufacture a photovoltaic device as described in one or more embodiments of the disclosure.

FIG. 5 is a graphical representation of the relationship between light adsorption and microstructural information of an absorber layer for a solar cell as described in one or more embodiments of the disclosure.

### SUMMARY

Embodiments in this disclosure may be described more fully hereinafter with reference to the accompanying drawings, in which embodiments of the disclosure are shown. This disclosure may, however, be embodied in many different forms and should not be construed as limited to the embodiments set forth herein; rather, these embodiments are provided so that this disclosure will be thorough and complete, and will fully convey the scope of the disclosure to those skilled in the art.

Embodiments described in this disclosure may provide systems and methods for implementing a high deposition rate of silicon layers used to manufacture photovoltaic devices. The systems and methods may be optimized to achieve high device quality related to, but not limited to, optimal light adsorption and resistance to light induced degradation. The high quality photovoltaic device may be achieved by a combination of plasma chamber design (e.g., inter-electrode separation) and plasma process parameters (e.g., pressure, applied RF voltage, etc.) to optimize the doped and/or intrinsic layers of the solar cell (e.g., p-i-n junction).

Example embodiments of the disclosure will now be described with reference to the accompanying figures.

### DETAILED DESCRIPTION

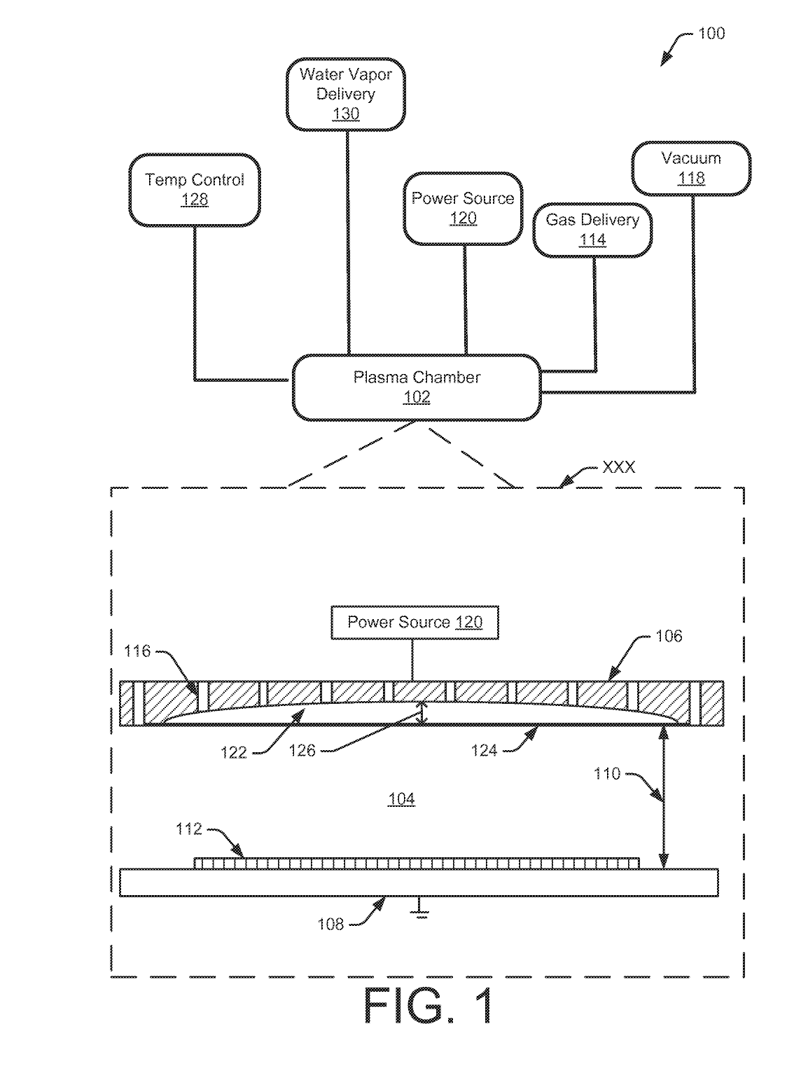

FIG. 1 is a simplified block diagram of a representative plasma processing system 100 that may include a plasma chamber 102 used to generate a relatively homogenous plasma discharge across a plasma processing region 104 disposed between a powered electrode 106 and a grounded electrode 108. Plasma uniformity within the plasma-processing region 104 may be optimized using a combination of hardware design and process conditions.

In one embodiment, plasma uniformity may be optimized by controlling the distance between the powered electrode 106 and the grounded electrode 108 in conjunction with the process pressure inside the plasma chamber 102. For example, as the pressure increases the plasma uniformity across the plasma-processing region 104 may be sustained if the separation distance 110 is relatively small enough when compared to the volume or design of the plasma chamber 102. The separation distance 110 may influence the diffusion path of deposition precursor chemical towards the substrate 112. Accordingly, in this embodiment, the separation distance 110 may range between 0.7 cm and 2 cm. In one specific embodiment, the separation distance may be limited from 0.9 cm to 1.6 cm. However, the separation distance 110 may be optimized depending on the pressure from the process gases (e.g., precursor chemical) during plasma processing.

In one instance, the precursor chemicals may be introduced to the plasma chamber 102 via a gas delivery system 114 that controls the flow rate into the plasma-processing region 104 via gas injection holes 116 in the powered electrode 106. The pressure in the plasma-processing region 104 may be controlled using a vacuum system 118 that controls the process pressure given the flow rates of the gases from the gas delivery system 114. The plasma may be generated when the powered electrode 106 receives power (e.g., radio frequency power) from the RF power source 120 and ionizes the chemical precursors or gas in the plasma-processing region 104. In this way, the ionized molecules of the plasma may be drawn towards the grounded electrode 108 and deposited on the substrate 112 to form one or more types of silicon layers of the photovoltaic devices. The process gases may include, but are not limited to, Argon, Nitrogen, Hydrogen, Silane, Diborane, and various dopant gases (e.g., phosphorus, arsenic, etc.).

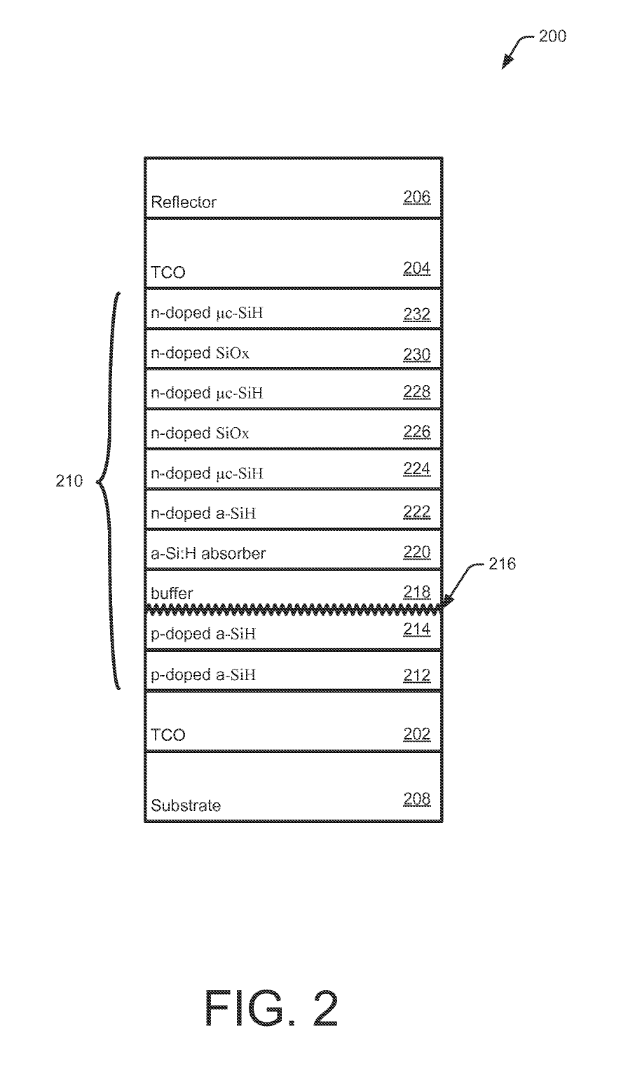

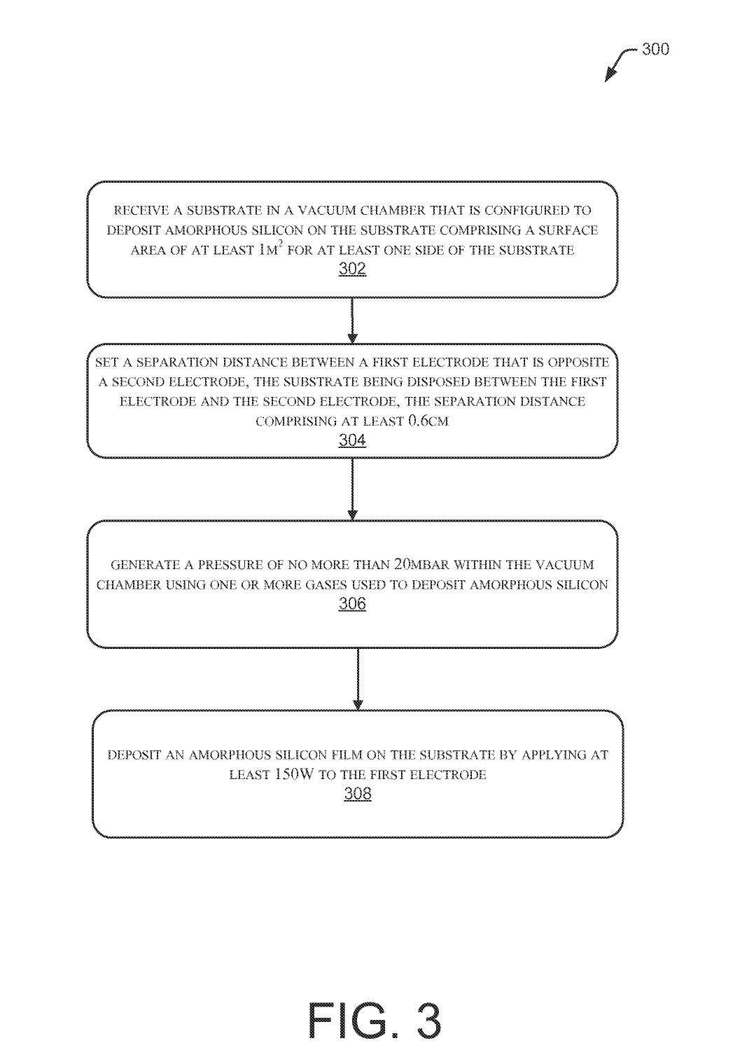

The quality and uniformity of the deposited layer on the substrate 108 may be optimized when operating within a regime characterized by the product of the pressure and the separation distance 110. For example, the separation distance 110 may vary with the pressure within a certain regime. In one embodiment, the product of the separation distance 110 and the pressure may be between 0.18-16 mbar·cm. In this way, when the process pressure is 0.7 mbar the separation distance 110 may range between 0.28 cm and 2.29 cm. Likewise, in another embodiment, when the separation distance 110 is 1 cm, the process pressure may range between 0.2 mbar and 1.6 mbar. Additional process condition embodiments will be described in the description of FIGS. 2 and 3. In addition to the product of distance and pressure, plasma uniformity in the plasma-processing region 104 may also contribute to the uniformity of the deposited layer.

The plasma uniformity may also be dependent upon the distribution of power across the plasma-processing region 104. The design of the powered electrode 106 may be used to influence the uniformity as shown in FIG. 1. In one instance, the powered electrode 102 may include a cavity 122 that may be at least partially covered by an insulating plate 124. The cavity 122 may be used to obtain a more uniform electrical field that may be generated when power is applied to the powered electrode 106. Broadly, the cavity 122 may be concave cavity within the powered electrode 106, as shown in FIG. 1. The cavity 122 may be sloped from an exterior surface of the powered electrode 106 to a maximum distance or lens distance 126 that may be near the center of the powered electrode 106.

The contents of the cavity 122 may vary depending on the desired process conditions being implemented on the substrate 112. The contents of the cavity 122 may affect the uniformity of the electric field generated during plasma processing. In one embodiment, the cavity 122 may be held under sub-atmospheric pressure conditions that may or may not include process gases. In another embodiment, the cavity 122 may also include a dielectric material that may be flush with the insulating plate 124 and/or the cavity 122 of the powered electrode 106.

The insulating plate 124 may cover the cavity 122 and may be separated from the substrate 112 by separation distance 110. This distance may be measured from the an exterior surface of the insulating plate 118 that may be facing the substrate 112 to a surface of the substrate 112 that may be facing the insulating plate 124. In this embodiment, the electrode separation distance 124 may be measured between the surfaces of the powered electrode 106 and the grounded electrode 108 that may be facing each other. In one embodiment, the thickness of the substrate 112 may be less than 5 mm. The thickness of the substrate 112 may or may not be included in the determination of the total separation distance 110. In one particular embodiment, the thickness of the substrate 112 may be approximately 3 mm. In one specific embodiment, the separation distance 110 may be no more than 2 cm.

In addition to plasma uniformity, temperature uniformity across the substrate 112 may also be used to control deposited film layer uniformity. A temperature control system 128 may be used to control the temperature of the substrate 112 via resistive heating of the grounded electrode 108. The temperature may be used to control the deposition rate of the silicon layer and the crystalline structure of the silicon layer. Depending on the temperature, the silicon layer may have an amorphous or microcrystalline structure that may affect the electrical properties of the layer. In addition to crystalline structure, the electrical properties of the silicon layer may also be influenced by dopants that may be introduced into the precursor chemical during plasma processing. Likewise, water vapor introduced between plasma processing steps may also influence the electrical properties of the photovoltaic device. In this instance, a water vapor delivery system 130 may be used to introduce water vapor into the plasma chamber 102 and will be described in detail in the descriptions of FIGS. 2 and 3.

In another embodiment, of the plasma chamber 102, the location of the vacuum ports is optimized to enable fluid communication between the pump (not shown) and the plasmas chamber 102. The location of the vacuum ports relative to the substrate 108 may vary. In one instance, the vacuum ports may be located in a sidewall (not shown) in the plasma chamber 102. In another instance, the vacuum ports may be located in a bottom wall (not shown) located in a plane that is below a horizontal plane that includes the front surface of the substrate 108.

The components of the plasma processing system 100 may be integrated together using one or more computer processing devices (not shown)) that enable communication between each of the components in such a way to implement the embodiments described in this disclosure.

FIG. 2 is a cross sectional view of one embodiment of a photovoltaic device 200 that may be manufactured using the embodiments described in FIG. 1 and the process conditions described below. Broadly, the photovoltaic device 200 may include an energy conversion portion (e.g., silicon layers, etc.) that may be bracketed between a first transparent conductive oxide layer (TCO) 202 and a second TCO layer 204. A reflector layer 206 may be adjacent to a surface the first TCO layer 202 that is opposite the energy conversion portion of the photovoltaic device 200. The reflector layer 206 may be used to reflect light back into the energy conversion portion that has travelled through the glass substrate 208, the first TCO layer 202, the energy conversion portion, and the second TCO layer 204. In this embodiment, the photovoltaic device 200 may be manufactured by depositing the illustrated layer on top of each other, starting with depositing the first TCO layer 202 on the glass substrate 208.

In the FIG. 2 embodiment, the photovoltaic device 200 may include a solar cell 210 that may include various layers of amorphous and microcrystalline silicon. However, in other embodiments, more than one solar cell 210 may be incorporated into the photovoltaic device 200, such that two or more solar cells 210 may be disposed between the first TCO layer 202 and the second TCO layer 204.

In one embodiment, the substrate 208 may include a transparent material or glass that may enable light to pass through from one surface and out at an opposing surface. The solar cell 210 may be deposited on to the substrate using several different processes that enable the solar cell to convert light into electrical energy. Prior to forming the solar cell 210, the first TCO layer 202 may be deposited onto the substrate 208 to form an electrode that may transport electrical current generated by the solar cell 210. The first TCO layer 202 may also pass light from surface to surface of the film.

In the FIG. 2 embodiment, the solar cell 210 a first p-doped amorphous silicon (a-Si:H) layer 212 with a thickness ranging from 1-6 nm, more particularly 2-4 nm. The first p-doped a-Si:H layer 212 may be deposited using a gaseous mixture containing SiH4, H2, and Trimethylboron (TMB) using gas flows, chamber temperature, chamber pressure, and RF-power conditions that enable a deposition rate of 1 A/s to 6 A/s, more particularly at 2 A/s to 5 A/s. Additionally, the first p-doped a-Si:H layer 212 may have a band gap energy of about 1.8±0.15 eV, a refractive index in the range 3.5-4.5, and an electrical conductivity higher than 10⁻⁵ Ω·cm⁻¹. Typically the first p-doped a-Si:H layer 212 may be optimized for a good electrical conductivity (due to its electrical contact with the first TCO layer 202) and a minimal light absorption (losses).

A second p-doped a-Si:H layer 214 with a thickness ranging from 5-25 nm, more particularly between 8-15 nm, may be deposited over the first p-doped a-Si:H layer 212. The layer may be deposited using a gaseous mixture containing SiH4, H2, TMB, and CH4 using gas flows, chamber temperature, chamber pressure, and RF-power conditions that enable a deposition rate of 1 A/s to 6 A/s, more particularly at 2 A/s to 5 A/s. Additionally, the first p-doped a-Si:H layer 212 may have a band gap energy of about 2.05±0.15 eV and is generally higher that the bandgap energy of the said first p-doped a-Si:H layer 212 by about 0.1-0.3 eV. The second p-doped a-Si:H layer 214 may include a refractive index in the range 3-4 and an electrical conductivity higher than 10⁻⁶ Ω·cm⁻¹. The typical tuning of second p-doped a-Si:H layer 214 ensures an optimal electric field into the device (so that all charge carriers are transported and collected properly) with minimal ohmic losses and a maximal transparency so that enough light will reach the absorber region of the device. An additional constraint of the second p-doped a-Si:H layer 214 is represented by its stability when exposed to illumination. Carbon incorporation into the film allows the control of bandgap energy and material transparency. However, large amounts of CH4 and thicker layers may lead to less stable devices. In another embodiment, the first p-doped a-Si:H layer 212 and the second p-doped a-Si:H layer 214 can be deposited “at once” with the mentioned properties controlled during the film growth by means of changing the PECVD conditions, as needed to deposit the combined film layer.

The second p-doped a-Si:H layer 214 may be followed by a dosing step 216 prior to depositing additional films of the solar cell 210. The substrate 208 may be removed from the plasma chamber 102, which may be exposed to a water-containing atmosphere for less than 10 minutes, more particularly less than 3 minutes. The water-containing atmosphere may be sustained at a pressure between 0.05 and 10 mbar, in particular between 0.05 and 5 mbar.

In another embodiment, the dosing step 216 may include placing the substrate 208 back into the plasma chamber 102 and exposing the substrate 208 to a plasma discharge with the water-containing atmosphere with or without the presence of H2. The plasma discharge may be sustained by applying an RF-power in the range of 50-500 W. In this step, the pressure in the plasma chamber 102 may be about 0.05-1 mbar. The plasma discharge may exist for less than 2 minutes, in particular for less than 1 minute, even more particularly for less than 30 seconds. The optimization of dosing step 216 may enable passivation of the boron deposited on the chamber walls during the deposition of the first p-doped a-Si:H layer 212 and the second p-doped a-Si:H layer 214 layer.

A buffer layer 218 may be deposited after the dosing step 216 and may include one or more a-Si:H layers and/or a-SiC:H layers. The one or more layers may have a total thickness summing to 4-16 nm, more preferentially 5-10 nm. The buffer layer(s) 218 may be deposited using SiH4-H2 mixtures with or without the addition of C-containing gases (such as CH4 or CO2). The gas flows, chamber temperature, gas pressure, and RF-power conditions can be chosen to ensure a deposition rate between 0.2 and 4.0 A/s. In one preferred embodiment the buffer layer 218 step includes a carbon containing gas, namely CH4, and may be provided to the plasma chamber 102 until about 50% of the desired thickness is deposited. The next approximately 25% of the layer is deposited using only half the amount of CH4 flow used before. The remaining portion of the buffer layer 219 may be obtained without or suppressing the CH4 flow. The “profiling” of C amount incorporate into the film during the C-4 step corresponds to a structural transition between the second p layer and the following absorber layer (to be described in step C-5). The optimization of buffer layer 218 may be done to block of boron penetration into the absorber layer 220. The C profile may be optimized to provide a smooth transition toward the absorber layer 220 and provide minimal sensitivity to light induced degradation (LID). The buffer layer 218 can also be tuned so that the bandgap energies are about 1.8±0.1 eV and the refractive index is in the range of 4-4.5.

An absorber layer 220 may be deposited after the buffer layer 218 and may include one or more a-Si:H layers having a total thickness summing to 150-300 nm, more preferentially 180-260 nm. The absorber layer 220 may be deposited using a SiH4-H2 gas mixtures and the discharge condition i.e. gas flows, chamber temperature, gas pressure and RF-power can be choose to ensure deposition rates in the range 1.0 to 10 A/s. In one embodiment a single intrinsic a-Si:H film is deposited as the absorber layer 220 at moderate deposition rates (2.5-3 A/s). In another embodiment a plurality of intrinsic layers (at least two) are deposited so that a high quality, slow growing film is the first one to be deposited after the buffer layer 218. The thickness of the slow growing film is at least 10% of the total absorber layer 220 thickness at deposition rate less than 2.5 A/s. The rest of the thickness may be completed using a faster deposition rate that is greater than 2.5 A/s. It is common knowledge for an expert in the field that intrinsic a-Si:H films are exposed to light induced degradation, which increase the material defects density and reduce the generated electrical power. The effect is quantified under standardized illumination conditions. The absorber layer 220 characteristics may include a bandgap energy of 1.69±0.02 eV and a refractive index between 4-5, more preferentially 4.5-4.9. Additionally, the ellipsometric k(500) constant is greater than 0.57, more preferentially greater than 0.6. The absorber layer 220 may also exhibit infrared microstructure factors (FTIR technique on Si-wafers) smaller than 5%, more preferentially smaller than 4%.

In one embodiment, an optimization method may be used for the absorber layer 220. The optimization method relies on specific techniques described below

A first n-doped a-Si:H layer 222 may be deposited on the absorber layer 220 with the thickness ranging from 1 to 25 nm, more particularly 1-20 nm. The first n-doped a-Si:H layer 222 may be deposited using a gas mixture containing SiH4, H2 and PH3 so that phosphorous atoms act as n dopant during the film growth. The gas flows, chamber temperature, gas pressure and RF-power condition can be chosen such that the first n-doped a-Si:H layer 222 growth rate is at least 2 A/s, more particularly between 2 and 5 A/s. The tuning of the first n-doped a-Si:H layer 222 may in film characteristics that may include, but are not limited to, a bandgap energy of about 1.7±0.02 eV, a refractive index ranging from 4.5 to 4.9 and an electrical conductivity greater than 1×10⁻³ Ω·cm⁻¹.

In one embodiment, the second TCO layer 204 and the reflector layer 206 may be deposited after the first n-doped a-Si:H layer 222 to form a solar cell device that may be used to convert light into energy. However, in the FIG. 2 embodiment, the solar cell 210 may be extended to include additional silicon layers prior to depositing the second TCO layer 204 and the reflector layer 206.

A first n-doped microcrystalline silicon (μc-Si:H) layer 224 may be deposited, on the first n-doped a-Si:H layer 222, with a thickness ranging from 5 to 15 nm, more preferentially 7-12 nm. The first n-doped μc-Si:H layer 224 can be performed using a SiH4-H2-PH3 gas mixture and the gas flows, chamber temperature, gas pressure and RF-power conditions can be choose so that a μc-Si:H growth is possible at deposition rates ranging from 0.5 to 3 A/s. In one embodiment , the first n-doped μc-Si:H layer 224 having a thickness ranging from 1 to 3 nm, can be combined with the following first n-doped silicon oxide (SiOx) layer 226 to from a sequence of silicon layer that may be repeated several times prior to depositing the second n-doped μc-Si:H layer 228. The dual-layer sequence may be repeated several times (2-7 times, preferentially 5 times) with the first n-doped μc-Si:H layer 224 eliminated in the last repetition. The tuning of the first n-doped μc-Si:H layer 224 may include the following film characteristics, the refractive index ranges from 4 to 4.5 and the electrical conductivity is greater than 1 Ωcm⁻¹.

A first n-doped silicon oxide (SiOx) layer 226 with a thickness ranging from 5-18 nm may include, but is not limited to, a refractive index 1.9 to 2.3, more particularly 1.95-2.2 and an electrical conductivity in the range 10⁻⁸-10⁻⁴ Ω·cm⁻¹, more particularly 4×10⁻⁸-2×10⁻⁵ Ω·cm⁻¹. The first n-doped SiOx layer 226 may be deposited using a SiH4-H2-PH3-CO2 gas mixture. The presence of CO2 (or gases containing oxygen) may be used to induce a decrease of the refractive index in the mentioned range. Since the factor (or combination of factors) decreasing the refractive index (such as a higher RF-power, or a larger amount of CO2) are also reducing the electrical conductivity of the film. It is typical for the manufacturing of first n-doped SiOx layer 226 that an optimal combination of refractive index, electrical conductivity and the deposition rate is to be achieved. The gas flows, chamber temperature, gas pressure and RF-power condition have been tuned to ensure the mentioned properties at deposition rates ranging from 1 to 4 A/s. The optimization of this layer may be used either as a standalone step or in combination with first n-doped μc-Si:H layer 224 may be performed in view of a fast growing film (>2 A/s) at small refractive index and simultaneously large electrical conductivities. The layer presence enables the solar cell 210 junction to generate an extra current density, which is a benefit for both single and multi junction solar convertors.

A second n-doped μc-Si:H layer 228, similar to the first n-doped μc-Si:H layer 224, may be deposited on the first n-doped SiOx layer 226. Followed by a second n-doped SiOx layer 230 being deposited on the second n-doped μc-Si:H layer 228. The second n-doped SiOx layer 230 being substantially similar to the first n-doped SiOx layer 226.

A third n-doped μc-Si:H layer 232 with a thickness ranging from 2 to 8 nm, more particularly from 3 to 6 nm may be deposited on the second n-doped μc-Si:H layer 228. The third n-doped μc-Si:H layer 232 may be deposited using a SiH4-H2-PH3 gas mixture; the gas flows, chamber temperature, gas pressure and RF-power conditions can be chosen so that a μc-Si:H growth is possible at deposition rates ranging from 1 to 3 A/s. The third n-doped μc-Si:H layer 232 may be tuned to include one or more of the following characteristics: refractive index ranges from 3.8 to 4.6 and the electrical conductivity is greater than 1 Ωcm⁻¹.

As shown in FIG. 2, the solar cell 210 comprising the silicon layer described above may be capped with a second TCO layer 204 and a reflector layer 206. The thicknesses of the first TCO layer 202 and second TCO layer 204 may range from 1-3 μm, more particularly 1.5-2.5 μm. In one embodiment, the first TCO layer 202 and second TCO layer 204 may be doped with boron atoms by means of diborane (B2H6) in a low-pressure chemical vapor deposition system at temperature below 200° C.

The first TCO layer 202 may be is optimized for a high electrical conductivity and a high degree of light scattering, while the second layer 204 (consisting in a single or a multi-layer structure) may be optimized for a long-term stability of the material.

The reflector layer 206 may be made using a material that may be able to reflect any light that passes out of the solar cell 210 back into the solar cell 210. The reflector may include a textured metallic composition that may increase the amount of light that is reflected back into the solar cell 210.

In addition to the process conditions describe above, Table I and Table II provide process conditions that may be used for the silicon layers shown in the FIG. 2 embodiment. Table II includes a process flow that does not include the dosing step 216.

TABLE I

| | | Gas mixture | | | |
|---|---|---|---|---|---|
| | | SiH4 | H2 | PH3 | TMB |
| Index | Layer Type | [sccm] | [sccm] | [sccm] | [sccm] |
| C-1 | p-doped a-Si: H | 500 (250-750) | 800 (400-1200) | — | 400 (200-600) |
| C-2 | p doped a-SiC: H | 350 (200-600) | 670 (300-1200) | — | 350 (200-600) |
| C-3 | H2O plasma treatment | — | (10-500)* | — | — |
| C-4 | a-Si: H and/or a-SiC: H | 300 (100-500) | 4000 (3000-7000) | — | — |
| | | 70 (20-150) | 2000 (1000-4000) | — | — |
| | | 70 (20-150) | 2000 (1000-4000) | — | — |
| C-5 | a-Si: H | 1000 (300-1500) | 1000 (300-1500) | — | — |
| | | 400 (200-600) | 2000 (1000-4000) | — | — |
| | | 625 (400-700) | 625 (400-700) | — | — |
| | | 500 (300-750) | 2500 (500-5000) | — | — |
| | | 600 (400-900) | 7500 (5000-12000) | | |
| | | 800 (500-1500) | 1500 (500-3000) | — | — |
| C-6 | n doped a-Si: H | 310 (200-500) | 1000 (700-1200) | 220 (100-400) | — |
| C-7 | n doped μc-Si: H | 60 (20-100) | 5000 (3000-7000) | 50 (20-100) | — |
| C-8 | n doped μc-SiOx | 75 (50-200) | 16000 (10000-20000) | 300 (200-1200) | — |
| C-8 | n doped μc-SiOx | 85 (50-200) | 16100 (10000-20000) | 1000 (800-1500) | — |
| C-9 | n doped μc-Si: H | 130 (30-300) | 8000 (5000-10000) | 200 (50-400) | — |

| | Gas mixture | | | | Wanted | |
|---|---|---|---|---|---|---|
| | CH4 | CO2 | RF Power | Pressure | Thickness | Gap |
| Index | [sccm] | [sccm] | [kW] | [mbar] | (nm) | [cm] |
| C-1 | — | — | 0.35 (0.2-1.0) | 0.5 (0.3-2.0) | 3 (1-6) | 1.6 |
| C-2 | 650 (350-1000) | — | 0.2 (0.15-1.0) | 0.5 (0.3-2.0) | 12 (5-25) | 1.6 |
| C-3 | — | (10-500)** | 0.3 (0.2-1.0) | 0.3 (0.2-5) | — | 1.6 |
| C-4 | 160 (50-350) | — | 0.3 (0.2-1.0) | 0.5 (0.3-2.0) | 7 (4-16) | 1.6 |
| | 30 (1-50) | — | 0.2 (0.1-1.0) | 0.5 (0.3-2.0) | | 1.6 |
| | — | — | 0.2 (0.1-1.0) | 0.5 (0.3-2.0) | | 1.6 |
| C-5 | — | — | 0.25 (0.15-0.6) | 0.3 (0.2-0.6) | 200 (180-260) | 1.6 |
| | — | — | 0.25 (0.15-0.6) | 0.7 (0.5-1.0) | | 1.6 |
| | — | — | 1.0 (0.5-1.5) | 0.7 (0.5-1.0) | | 1.6 |
| | — | — | 0.4 (0.15-0.75) | 1.5 (1.0-3.0) | | 1.6 |
| | | | 0.6 (0.5-0.9) | 3.5 (3.0-6.0) | | 1.6 |
| | — | — | 1.5 (1.0-3.5) | 9.0 (4.0-16.0) | | 0.7 |
| C-6 | — | — | 0.4 (0.3-0.6) | 0.5 (0.3-3) | 5 (1-25) | 1.6 |
| C-7 | — | — | 2.0 (1.0-4.0) | 3 (2.0-5.0) | 9 (5-15) | 1.6 |
| C-8 | — | 125 (100-300) | 4.5 (2.5-6.0) | 4.7 (2.5-7.0) | 15 (5-18) | 1.6 |
| C-8 | — | 275 (200-500) | 4.5 (2.5-6.0) | 4.7 (2.5-7.0) | 105 (80-130)*** | 1.6 |
| C-9 | — | — | 3.5 (2.0-5.0) | 3 (2.0-5.0) | 4 (2-8) | 1.6 |

*in one variant of the process a H2 flow can be added over the H2O vapours
**in one variant of the process CO2 flow can be added over the H2O
***in one variant the layer can be deposited at one with about 105 nm thickness

TABLE II

| | | Reference | Deposition | Film | Refractive Index | |
|---|---|---|---|---|---|---|
| | | thickness | Rate | Uniformity | n (500) | k(500) |
| Index | Layer Type | [nm] | [A/s] | [%] | [-] | [-] |
| C-1 | p-doped a-Si: H | 200 ± 20 | 2-5 (1-6) | <10 | 4.0-4.4 (3.6-4.6) | 0.4-0.5 (0.35-0.55) |
| C-2 | p doped a-SiC: H | 200 ± 20 | 2-5 (1-6) | <10 | 3.3-3.7 (3.0-4.0) | 0.23-0.26 (0.2-0.3) |
| C-4 | a-Si: H and/or a-SiC | 200 ± 20 | 0.2-4 (0.1-6) | <10 | 4.2-4.4 (4.0-4.6) | 0.4-0.43 (0.38-0.46) |
| C-5 | a-Si: H | 300 ± 20 | 2-5 (1-10) | <10 | 4.5-4.9 (4.0-5.0) | >0.57 (>0.6) |
| C-6 | n doped a-Si: H | 200 ± 20 | 2-5 (>2) | <10 | 4.5-4.75 (4.4-4.9) | 0.55-0.6 (0.52-0.62) |
| C-7 | n doped μc-Si: H | 80 ± 20 | 0.5-3 (0.2-5) | <20 | 4.0-4.3 (3.8-4.5) | 0.16-0.19 (0.12-0.22) |
| C-8 | n doped μc-SiOx | 80 ± 20 | 2-3 (1-5) | <15 | 1.95-2.2 (1.9-2.3) | <0.1 |
| C-9 | n doped μc-Si: H | 80 ± 20 | 1-3 (0.5-5) | <20 | 4.1-4.3 (3.8-4.6) | 0.2-0.22 (0.18-0.24) |

| | Band Gap | Electrical | | |
|---|---|---|---|---|
| | E_Tauc | Conductivity | R factor | R* factor |
| Index | [eV] | [Ω ± cm]⁻¹ | FTIR [%] | Raman [%] |
| C-1 | 1.8 ± 0.15 | >10⁻⁵ | — | — |
| C-2 | 2.05 ± 0.15 | >10⁻⁶ | — | — |
| C-4 | 1.8 ± 0.1 | — | — | — |
| C-5 | 1.69 ± 0.2 | — | 2.5-5 (2-6) | 13.5-14.5 (13-15) |
| C-6 | 1.7 ± 0.02 | >10⁻³ | — | — |
| C-7 | — | 1.0-10 | — | — |
| C-8 | — | 10⁻³-10⁻⁴ | — | — |
| | | (4 × 10⁻⁸-2 × 10⁻⁵) | | |
| C-9 | — | >1 | — | — |

FIG. 3 is a flow diagram for a method 300 used to manufacture the silicon layers of one embodiment of a photovoltaic device. The silicon layers maybe deposited using a PECVD system as shown in FIG. 1. The silicon layers may include varying crystalline structure, dopant levels, and thicknesses in such as way that may enable the conversion of light into electrical current. In one embodiment, the substrates 208 that may be used to manufacture the PV devices may include glass or another relatively transparent material on which the silicon layers may be formed. The substrates 208 may be at least 1.5 mm thick and may have a surface area of at least at least 1 m² for at least one side of the substrate 208.

At block 302, the plasma chamber 102 may receive a substrate 208 and the plasma processing system 100 may be configured to deposit silicon layers. In one embodiment, the silicon layers may be deposited using plasma-enhanced chemical vapor deposition (PECVD) techniques. The plasma may be generated using precursor chemicals that may be exposed to the substrate 208 under various temperatures, pressures, and power settings. Additionally, the separation distance 110 between the powered electrode 106 that ignites the plasma and the substrate 208 may be optimized to form silicon layers of a desired quality and/or characteristic.

At block 304, the plasma processing system 100 may set the separation distance 110 between a first electrode (e.g., powered electrode 106) that is opposite a second electrode (e.g., grounded electrode 108) prior to igniting the plasma. In this instance, the substrate 208 being disposed between the first electrode and the second electrode and the separation distance 110 may be at least 0.6 cm

At block 306, the plasma processing system 100 may generate a pressure of no more than 20 mbar within the vacuum chamber or plasma chamber 102 using one or more gases used to deposit amorphous silicon. The gases may include, but are not limited to, SiH₄.

At block 308, the plasma processing system 100 may begin depositing an amorphous silicon film on the substrate 208 by applying at least 150 W to the first electrode. The chemical precursors (e.g., SiH₄, etc.) within the plasma chamber 102 may be ignited to form plasma used to deposit a silicon layer on the substrate 208. The silicon deposition process may be implemented as described in the description of FIG. 2, the embodiments described in Table I, Table II, or the method 400 described below.

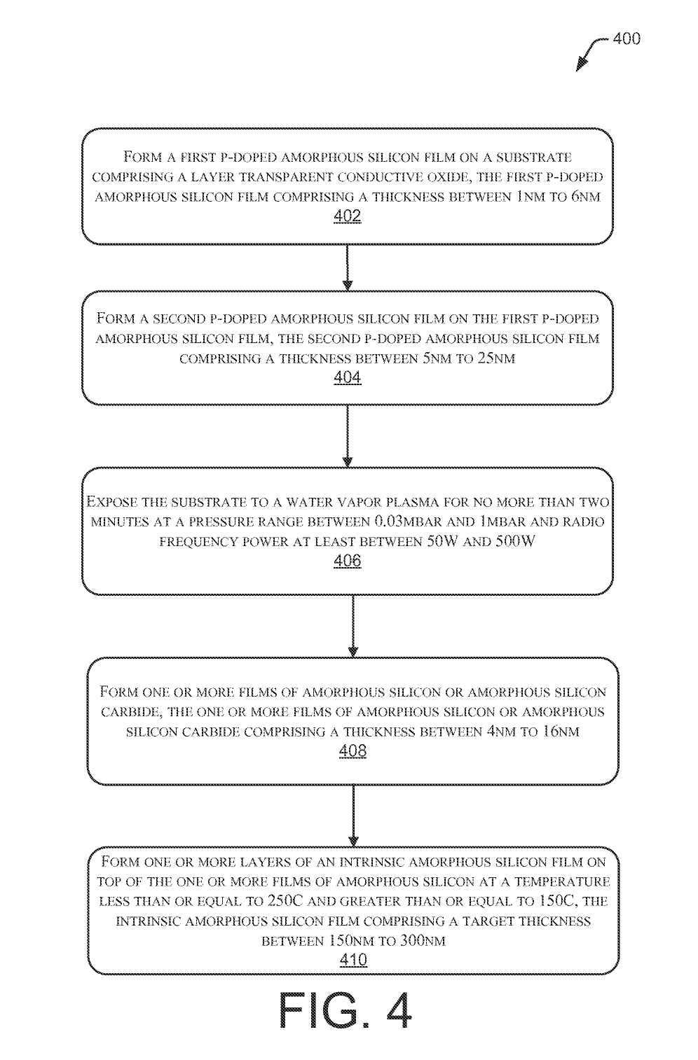

FIG. 4 is a flow diagram for a method 400 used to manufacture the silicon layers of one embodiment of a photovoltaic device. The silicon layers may be deposited using a plasma processing system 100 that be configured to vary the structure and composition of each other silicon layers. The method 400 is merely exemplary of one method and the steps described below may be performed in any order and may even omit certain steps that may be used to form a portion of the photovoltaic device. Additional processing equipment that is known in the art may be used to form the layers around the silicon layers.

At block 402, the plasma processing system 100 may form a first p-doped amorphous silicon film 212 on a substrate 208 that may already include a transparent conductive oxide layer 202. In one embodiment, the first p-doped amorphous silicon film 212 may have a thickness between 1 nm to 6 nm. Please see Table I and/or Table II for additional process conditions for this layer.

At block 404, the plasma processing system 100 may form a second p-doped amorphous silicon film 214 on the first p-doped amorphous silicon film 212. The second p-doped amorphous silicon film 214 may have a thickness between 5 nm to 25 nm. Please see Table I and/or Table II for additional process conditions for this layer.

At block 406, the plasma chamber 102 may be exposed to water vapor plasma, with or without the substrate 208, for no more than two minutes at a pressure range between 0.05 mbar and 1 mbar and radio frequency power at least between 50 W and 500 W. In one embodiment, the radio frequency power should be at least 200 W. Please see Table I and/or Table II for additional process conditions for this layer. As shown in Table II, the water vapor plasma step may be omitted as needed.

At block 408, the plasma processing system 100 may form one or more films of amorphous silicon or amorphous silicon carbide (e.g., buffer layer 218). The one or more films of amorphous silicon or amorphous silicon carbide may have a thickness between 4 nm to 16 nm. Please see Table I and/or Table II for additional process conditions for this layer.

In one embodiment, the plasma processing system 100 may use a carbon containing gas until a first portion of the thickness for the one or more films of amorphous silicon or amorphous silicon carbide is formed. Then, the plasma processing system 100 may use a non-carbon containing gas until a second portion of the thickness is formed. In one particular embodiment, the first portion comprises about fifty percent of the thickness for the one or more films of amorphous silicon or amorphous silicon carbide, and the second portion comprises about fifty percent of the thickness for the one or more films of amorphous silicon or amorphous silicon carbide.

At block 410, the plasma processing system 100 may form one or more layers of an intrinsic amorphous silicon film (e.g., absorber layer 220) on top of the one or more films of amorphous silicon (e.g., buffer layer 218) at a temperature between 150 C and 250 C. The intrinsic amorphous silicon film has a thickness between 150 nm to 300 nm. In one specific embodiment, the target thickness is between 180 nm and 260 nm. Please see Table I and/or Table II for additional process conditions for this layer.

In one embodiment, the absorber layer 220 may include forming a first layer of the intrinsic amorphous silicon film at a first deposition rate and a second layer of the intrinsic amorphous silicon film at a second deposition rate that is greater than the first deposition rate. The first layer may have a thickness that is at least twenty percent of the target thickness for the absorber layer 220. Accordingly, the second layer of the intrinsic amorphous silicon film may have a thickness that is no more than eighty percent of the target thickness for the absorber layer 220.

In one embodiment, the absorber layer 220 may include forming a first layer of the intrinsic amorphous silicon film at a first deposition rate and a second layer of the intrinsic amorphous silicon film at a second deposition rate that is greater than the first deposition rate. The first layer may have a thickness that is at least ten percent of the target thickness for the absorber layer 220. Accordingly, the second layer of the intrinsic amorphous silicon film may have a thickness that is no more than ninety percent of the target thickness for the absorber layer 220.

In another embodiment, the two layer absorber layer 220 may be formed by a first layer of the intrinsic amorphous silicon film at a first deposition rate, the first layer have a thickness that is not more than eighty percent of the target thickness for the absorber layer 220. A second layer of the intrinsic amorphous silicon film may be formed using a second deposition rate that is lower than the first deposition rate. The second layer of the intrinsic amorphous silicon film may have a thickness that is no more than twenty percent of the target thickness of the absorber layer 220.

In another embodiment, the two layer absorber layer 220 may be formed by a first layer of the intrinsic amorphous silicon film at a first deposition rate, the first layer have a thickness that is not more than ninety percent of the target thickness for the absorber layer 220. A second layer of the intrinsic amorphous silicon film may be formed using a second deposition rate that is lower than the first deposition rate. The second layer of the intrinsic amorphous silicon film may have a thickness that is no more than ten percent of the target thickness of the absorber layer 220.

Following the absorber layer 220, the method 400 may also include depositing additional silicon layers as shown in Table I and Table II. In one embodiment, the additional layers may at least include: an n-doped amorphous silicon film 222 having a thickness between 1 nm to 25 nm, a first n-doped microcrystalline film 224 having a thickness between 5 nm to 15 nm, a second n-doped silicon oxide layer 226 a thickness between 5 nm to 18 nm, a third n-doped microcrystalline layer on top of the second n-doped microcrystalline film, the third n-doped microcrystalline film 228 having a thickness between 2 nm to 8 nm. The solar cell 210 formed by the silicon layers described above may be capped by a TCO layer 204 and a reflectors layer 206.

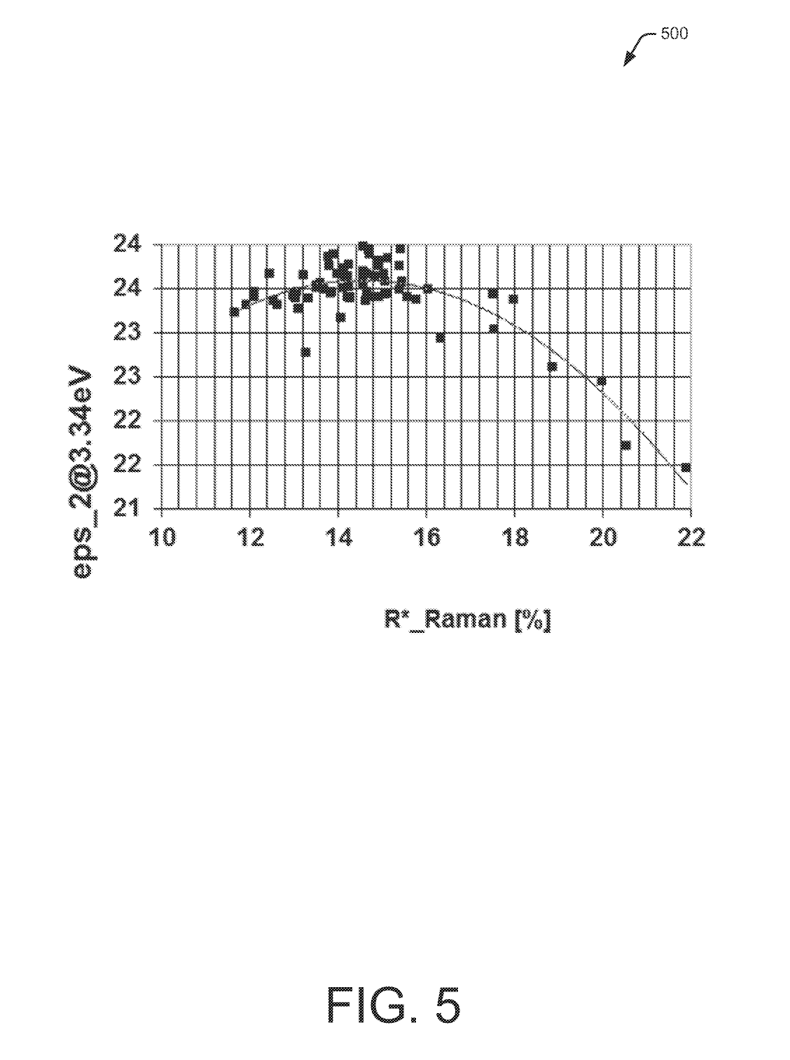

FIG. 5 is a graphical representation of the relationship between light adsorption and microstructural information of an absorber layer 220. The properties of the absorber layer 220 may influence the performance and stability of the solar cell 210. In addition, the ability to deposit absorber layer 220 quickly and uniformly over large areas may lead to particularly cost-efficient devices. The apparatus described in FIG. 1 not only allows a fast and uniform deposition of necessary thin films, but enables certain ranges of film properties at particularly attractive growing rates. For instance, the apparatus of FIG. 1 can be used by a person skilled in the art to reproduce optimal absorber layers 220 (intrinsic layers) that can be successfully used in a solar cell 210. One approach to the optimization may be explained using the relationship between light adsorption capability and the microstructural formation of the absorber layer 220.

One approach to evaluate material sensitivity to LID may be by using FTIR (Fourier Transform Infrared spectroscopy) material spectra by means of the so-called infrared microstructure factor R. For those skilled in the art, R factor evaluates the Si-H2 and Si-H bonds peaks at 2080 and 2000 cm-1 of the FTIR spectra, providing microstructural information. The method is a semi-empirical procedure. As the infrared light does not transmit through glass, standard state of the art evaluation of R factor is performed on a Si-wafer and the result extrapolated to describe the growth mechanism on glass. A more significant handicap of the procedure is related to sensitivity of the method when comparing already good films exhibiting similar, but not identical properties (as measured by FTIR on Si-wafers). It is in this point that the film optimization using the FTIR procedure reaches its limits and may introduce errors as big as 30-40% from the measured value. The exact reasons for the error may be related to signal/noise ratio or arbitrary background line extraction.

Present knowledge indicates that the microstructure factor has almost a linear increase with the deposition rate and with the gas pressure. Using the apparatus shown in FIG. 1 and the optimization procedure to be described, process conditions can be selected to enable an essential constant value of microstructure factor (about 3.5±1%) when increasing the deposition rate from 1.5 to 6 A/s or, alternatively, when the gas pressure is varied in the range 0.3-3.5 mbar.

In one embodiment, the Raman spectroscopy measurements have been used and an equivalent R* factor has been evaluated to get closer to the type of film deposited on the glass substrate 208. Similar to its FTIR correspondent, the R* evaluates Si-H and Si-H2 bonds in the material. However, the spectral region corresponding to Si-H is independently fitted avoiding the contribution of Si-H2. The second fitting step determines the total common area of Si-H and Si-H2. Since the R* value is calculated as R*=(Atotal−ASiH)/Atotal any change in fitting peaks positions or width do not affect the results. Preferred fitting region for Si-H is 1880 cm⁻¹-2050 cm⁻¹. Preferred fitting region for total area: 1880-2250 cm⁻¹.

In parallel with the measurement of R*, ellipsometry measurements have been used. It is widely known for those skilled in the art that the peak of the imaginary part of the complex dielectric function of a-Si:H, ε2, shows the fundamental light absorption and can be considered as an indication of a-Si:H network density. Thus, a maximum absorption and light utilization is expected in a compact network without empty spaces, which may result during the growth. These empty spaces known as micro-voids, are responsible for an insufficient absorption performance. Ideal growth conditions of an a-Si:H network lead to a dense structure without internal micro-voids. During the growth phase, cross-linking reactions determine the elimination of excess hydrogen, a typical good layer having an amount of about 10% hydrogen still present within the network, being the estimated corresponding material density around 2.1-2.25 g/cm³

In view of the above observations, the optimization can be summarized as follows:

Find out the minimal SiH4 and H2 flows (1:1 dilution) able to ensure a stable pressure around 0.25 ±0.1 mbar within the PECVD chamber.

Multiply the flows by a factor 2-10, preferentially 3-6. The new flows should extend in a significant amount the pressure range accessible in the chamber. For illustrative purposes, the range 0.3-3 mbar may be used as an example.

For a certain pressure (e.g. 0.3 mbar), perform the deposition of the absorber layer 220 by increasing successively the RF-power and measure the R* and ε2 average values over the substrate as shown in FIG. 4. R* values will decrease at higher RF powers, values as small as 10 being reachable. The absorber layers 220 having R* values in the range 10-17 exhibit different ε2 values. By choosing the absorber layers 220 having the largest light absorption (highest ε2) and a minimal R* values may optimize the light absorption of the absorber layer 220 ensuring simultaneously its stability against light induced degradation. In this embodiment, R* optimum ranges from 13.5 to 14.5 for a ε2 about 23.6. The dependence of ε2 on the R* values is shown in FIG. 4. The points correspond to different deposition conditions. Further changes in process pressure will modify the R* values. In order to keep R* in the in the desired domain, flow changes (out of 1:1 dilution) or modification of the RF-power may have to be performed. In practice, the increase in pressure may be linked to the increase of hydrogen dilution.

Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

The terms and expressions, which have been employed herein, are used as terms of description and not of limitation. In the use of such terms and expressions, there is no intention of excluding any equivalents of the features shown and described (or portions thereof), and it is recognized that various modifications are possible within the scope of the claims. Other modifications, variations, and alternatives are also possible. Accordingly, the claims are intended to cover all such equivalents.

While certain embodiments of the invention have been described in connection with what is presently considered to be the most practical and various embodiments, it is to be understood that the invention is not to be limited to the disclosed embodiments, but on the contrary, is intended to cover various modifications and equivalent arrangements included within the scope of the claims. Although specific terms are employed herein, they are used in a generic and descriptive sense only, and not for purposes of limitation.

What is claimed:

1. A vacuum chamber for depositing films for solar devices, comprising:
a pressure control system configured to control a process pressure in the vacuum chamber that is configured to deposit amorphous silicon on a substrate comprising a surface area of at least 1 m²;
a first active electrode is configured to provide alternating power to a plasma processing region of the vacuum chamber; and
a second electrode that is disposed opposite the first electrode and is configured to be separated from the first electrode by a separation distance that is based, at least in part, on an inter-electrode separation range comprising a product of the process pressure and the separation distance, wherein the inter-electrode separation range comprises a range of values between 0.18 mbar·cm and 16 mbar·cm, and wherein the process pressure comprises a pressure of at least 0.2 mbar and the separation distance comprises a distance of at least 0.9 cm.

2. The vacuum chamber of claim 1, further comprising at least one gas outlet on a vertical side of the vacuum chamber.

3. The vacuum chamber of claim 1, further comprising at least one gas outlet disposed proximate to the substrate.

4. A method for making a portion of a solar device, comprising receiving a substrate in a vacuum chamber that is configured to deposit amorphous silicon on the substrate comprising a surface area of at least 1 m² for at least one side of the substrate;
setting a separation distance between a first electrode that is opposite a second electrode, the substrate being disposed between the first electrode and the second electrode, the separation distance comprising at least 0.6 cm;
generating a pressure of no more than 20 mbar within the vacuum chamber using one or more gases used to deposit amorphous silicon;
depositing an amorphous silicon film on the substrate by applying at least 150 W to the first electrode.

5. The method of claim 4, wherein the substrate comprises a thickness of at least 1.5 mm.

6. The method of claim 4, wherein the first electrode comprises:
an electrode lens comprising a concave portion; and
a dielectric plate that covers at least a portion of the concave portion, the dielectric plate being no more than 3 mm from the concave portion, and the separation distance being measured from the substrate surface to the dielectric plate.

7. The method of claim 6, wherein the vacuum chamber is combined with one or more of the following:
a radio frequency power generator coupled to the electrode;
a water vapor delivery component coupled to the vacuum chamber;
a dopant delivery component coupled to the vacuum chamber, the dopant delivery component comprising a boron dopant and a phosphorus dopant;
a heating component coupled to the vacuum chamber;
a pump component coupled to the vacuum chamber;
a temperature control system configured to control and maintain the substrate at a temperature range between 150 C to 250 C; and
a gas distribution system configured to control one or more of the following gases: SiH₄, H₂, Ar, N₂, NH₃, F₂, CO₂, CH₄, PH₃, TMB, NF₃ or O₂.

8. A method for making a portion of a solar device, comprising:
forming a first p-doped amorphous silicon film on a substrate comprising a layer transparent conductive oxide, the first p-doped amorphous silicon film comprising a thickness between 1 nm to 6 nm;
forming a second p-doped amorphous silicon film on the first p-doped amorphous silicon film, the second p-doped amorphous silicon film comprising a thickness between 5 nm to 25 nm;
exposing the substrate to a water vapor plasma for no more than two minutes at a pressure range between 0.05 mbar and 1 mbar and radio frequency power at least between 50 W and 500 W;
forming one or more films of amorphous silicon or amorphous silicon carbide, the one or more films of amorphous silicon or amorphous silicon carbide comprising a thickness between 4 nm to 16 nm; and
forming one or more layers of an intrinsic amorphous silicon film on top of the one or more films of amorphous silicon at a temperature less than or equal to 250 C and greater than or equal to 150 C, the intrinsic amorphous silicon film comprising a target thickness between 150 nm to 300 nm.

9. The method of claim 8, further comprising:
forming an n-doped amorphous silicon film on top of the intrinsic amorphous silicon film, the n-doped amorphous silicon film comprising a thickness between 1 nm to 25 nm;
forming a first n-doped microcrystalline film on top of the n-doped amorphous silicon film, the first n-doped microcrystalline film comprising a thickness between 5 nm to 15 nm;
forming a second n-doped microcrystalline layer on top of the first n-doped microcrystalline film using oxygen, the second n-doped microcrystalline film comprising a thickness between 5 nm to 18 nm; and
forming a third n-doped microcrystalline layer on top of the second n-doped microcrystalline film, the third n-doped microcrystalline film comprising a thickness between 2 nm to 8 nm.

10. The method of claim 8, wherein the forming of one or more layers of an intrinsic amorphous silicon film comprises:
forming a first layer of the intrinsic amorphous silicon film using a first dilution ratio between 2:1 and 5:1 of H₂ to SiH₄, the first layer comprising a thickness that is at least ten percent of the target thickness; and
forming a second layer of the intrinsic amorphous silicon film using a second dilution ratio between 8:1 and 12:1 of H₂ to SiH₄, the second layer of the intrinsic amorphous silicon film comprises a thickness that is no more than ninety percent of the target thickness.

11. The method of claim 8, wherein the forming of the first p-doped amorphous silicon film, the second p-doped amorphous silicon film, the exposing of the substrate to the water vapor plasma, the one or more films of amorphous silicon or amorphous silicon carbide, the forming one or more layers of an intrinsic amorphous silicon film on top of the one or more films of amorphous silicon are implemented in a single process chamber.

12. The method of claim 11, wherein the single process chamber comprises:
an electrode configured to provide alternating power to a plasma processing region of the system; and
a substrate surface that is configured to support the substrate, and is substantially parallel to the electrode, and is separated from the electrode by a separation distance comprising a distance of no more than 2 cm.

13. The method of claim 8, wherein the forming of the one or more films of amorphous silicon or amorphous silicon carbide comprises:
using a carbon containing gas until a first portion of the thickness for the one or more films of amorphous silicon or amorphous silicon carbide is formed; and
using a non-carbon containing gas until a second portion of the thickness for the one or more films of amorphous silicon is formed.

14. The method of claim 13, wherein the first portion comprises about fifty percent of the thickness for the one or more films of amorphous silicon or amorphous silicon carbide, and the second portion comprises about fifty percent of the thickness for the one or more films of amorphous silicon.

15. The method of claim 8, wherein the target thickness comprises a thickness of at between 180 nm and 260 nm.

16. The method of claim 8, wherein the radio frequency power comprises at least 200 W.

17. The method of claim 8, wherein the forming of one or more layers of an intrinsic amorphous silicon film comprises:
forming a first layer of the intrinsic amorphous silicon film using a first dilution ratio between 8:1 and 12:1 of H₂ to SiH₄, the first layer comprising a thickness that is not more eighty percent of the target thickness; and
forming a second layer of the intrinsic amorphous silicon film using a second dilution ratio between 2:1 and 5:1 of H₂ to SiH₄ the second layer of the intrinsic amorphous silicon film comprises a thickness that is no more than twenty percent of the target thickness.

18. The method of claim 8, wherein the forming of one or more layers of an intrinsic amorphous silicon film comprises:
forming a first layer of the intrinsic amorphous silicon film using a first dilution ratio between 2:1 and 5:1 of H₂ to SiH₄, the first layer comprising a thickness that is at least twenty percent of the target thickness; and
forming a second layer of the intrinsic amorphous silicon film using a second dilution ratio between 8:1 and 12:1 of H₂ to SiH₄, the second layer of the intrinsic amorphous silicon film comprises a thickness that is no more than eighty percent of the target thickness.

19. The method of claim 8, wherein the forming of one or more layers of an intrinsic amorphous silicon film comprises:
forming a first layer of the intrinsic amorphous silicon film using a first dilution ratio between 8:1 and 12:1 of H₂ to SiH₄, the first layer comprising a thickness that is at least ten percent of the target thickness; and
forming a second layer of the intrinsic amorphous silicon film using a second dilution ratio between 2:1 and 5:1 of H₂ to SiH₄, the second layer of the intrinsic amorphous silicon film comprises a thickness that is no more than ninety percent of the target thickness.
